(19) United States
(12) Patent Application Publication
(10) Pub. No.: US 2011/0064545 A1
(43) Pub. Date: Mar. 17, 2011

(54) SUBSTRATE TRANSFER MECHANISM WITH PREHEATING FEATURES

(75) Inventors: TETSUYA ISHIKAWA, Saratoga, CA (US); Lily L. Pang, Fremont, CA (US); Quyen D. Pham, Santa Clara, CA (US); Donald J.K. Olgado, Palo Alto, CA (US)

(73) Assignee: APPLIED MATERIALS, INC., Santa Clara, CA (US)

(21) Appl. No.: 12/882,508

(22) Filed: Sep. 15, 2010

Related U.S. Application Data
(60) Provisional application No. 61/242,924, filed on Sep. 16, 2009.

(51) Int. Cl. H01L 21/677

(52) U.S. Cl. 414/217; 414/222.01; 414/806

(57) ABSTRACT

Embodiments of the present invention provide apparatus and method for heating one or more substrates during transfer. One embodiment provides a robot blade assembly for supporting a substrate or a substrate carrier thereon. The robot blade assembly comprises a base plate, an induction heating assembly disposed on the base plate, and a top plate disposed above the induction heating assembly. Another embodiment provides an induction heating assembly disposed over a transfer chamber having a substrate transfer mechanism disposed therein.

### CROSS REFERENCE TO RELATED APPLICATIONS

This application claims benefit of U.S. Provisional Patent Application Ser. No. 61/242,924 (Attorney Docket No. 13300L), filed Sep. 16, 2009, which is incorporated herein by reference.

### BACKGROUND OF THE INVENTION

1. Field of the Invention

Embodiments of the present invention relate to apparatus and methods for processing substrates. Particularly, embodiments of the present invention provide apparatus and methods for transferring substrates during processing.

2. Description of the Related Art

In manufacturing of semiconductor devices, substrates sometimes are processed at high temperatures. In existing systems, substrates generally remain in the processing chamber to cool off after processing at high temperatures to avoid breaking from thermal shock. Cooling off the substrates in the processing chamber takes away production time from the processing chamber causing cost of ownership to increase. Additionally, cooling off substrates in the processing chamber requires frequent cooling down and heating up of the processing chamber causing temperature swings in the processing chamber. The temperature swings in the processing chamber may cause deposits or films formed on internal surfaces of the processing chamber to flake off and increase particle contamination. Frequent cooling and heating of the processing chamber also increases energy cost.

Embodiments of the present invention provide methods and apparatus for substrate transferring before, after or between high temperature processing to avoid thermal shock, increase efficiency of processing chambers, and reduce energy consumption.

### SUMMARY OF THE INVENTION

Embodiments of the present invention generally provide apparatus and methods for transferring substrate during processing. More particularly, embodiments of the present invention provide a substrate transfer mechanism for heating substrates and/or controlling temperature of substrates during transferring.

One embodiment of the present invention provides a robot blade assembly for supporting a substrate or a substrate carrier thereon. The robot blade assembly comprises a base plate, an induction heating assembly disposed on the base plate, and a top plate disposed above the induction heating assembly.

Another embodiment of the present invention provides a cluster tool. The cluster tool comprises a transfer chamber having a transfer volume, a load lock coupled to transfer chamber, and one or more processing chambers coupled to the transfer chamber. The one or more processing chambers are configured to processing substrates at elevated temperature. The cluster tool further comprises a substrate transfer mechanism disposed in the transfer volume and configured to transfer substrates among the load lock and the one or more processing chambers, and an induction heating assembly configured to heat substrates being transferred by the substrate transfer mechanism.

Yet another embodiment of the present invention provides a method for processing one or more substrates. The method comprises transferring the one or more substrates from a first chamber to a second chamber by a transfer mechanism while heating the one or more substrates using an induction heating element to a first temperature, and processing the one or more substrates in the second chamber at a second temperature. The first temperature is substantially close to and lower than second temperature.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of a cluster tool in accordance with one embodiment of the present invention.

FIG. 2A is a schematic top view of a robot in accordance with one embodiment of the present invention.

FIG. 2B is a schematic top view of a robot blade supporting a substrate carrier.

FIG. 3 is a schematic section view of an end effector for a robot according to one embodiment of the present invention;

FIG. 4A is an exploded view of an end effector with one embodiment of the present invention.

FIG. 4B is a sectional side view of the end effector of FIG. 4A.

FIG. 4C is a sectional view of a coil for an induction heating element in accordance with one embodiment of the present invention.

FIG. 5 is a coil arrangement in accordance with one embodiment of the present invention.

FIG. 6 schematically illustrates a coil arrangement in accordance with one embodiment of the present invention.

FIG. 7 is a sectional view of a transfer chamber with one or more induction heating elements according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally provide apparatus and methods for transferring substrates during processing. More particularly, embodiments of the present invention provide a substrate transfer mechanism for heating substrates and/or controlling temperature of substrates during transferring.

Embodiments of the present invention provide apparatus and methods for transferring substrates at high temperature without thermal shock, therefore, improving throughput by eliminating cooling and heating periods during processing.

In one embodiment of the present invention, a substrate transfer mechanism comprises a transfer blade having an induction heating assembly configured to provide induction heating to substrates and/or substrate carriers being transferred. In one embodiment, the induction heating assembly comprises one or more planar spiral coils configured to heat substrates and/or a carrier of substrates with inductive energy. In one embodiment, the transfer blade further comprises a reflective foil configured to reflect the electromagnetic field towards the substrate and/or carrier being heated. In one embodiment, the transfer blade comprises an infrared reflective film to avoid heating of the transfer blade and the one or more spiral planar coils.

In another embodiment, heating elements are disposed in a transfer path of the substrates, for example, in a transfer chamber, to heat the substrates or maintain the substrates at a high temperature during transfer. In one embodiment, one or more induction heating elements are disposed over a chamber lid of a transfer chamber.

Substrate transfer mechanisms of the present invention can be used to rapidly heat substrates and/or maintain substrates at a high temperature while transferring the substrates. In one embodiment, a substrate transfer mechanism with induction heating elements is used to preheat substrates during transfer to a hot processing chamber to avoid thermal shock. In another embodiment, a substrate transfer mechanism with induction heating elements is used to retrieve substrates at a high temperature without thermal shock by maintaining the substrates at a high temperature using induction heating. In another embodiment, one or more portions of the substrate transfer path, such as a transfer chamber, are heated to prevent thermal shock to substrates during transfer.

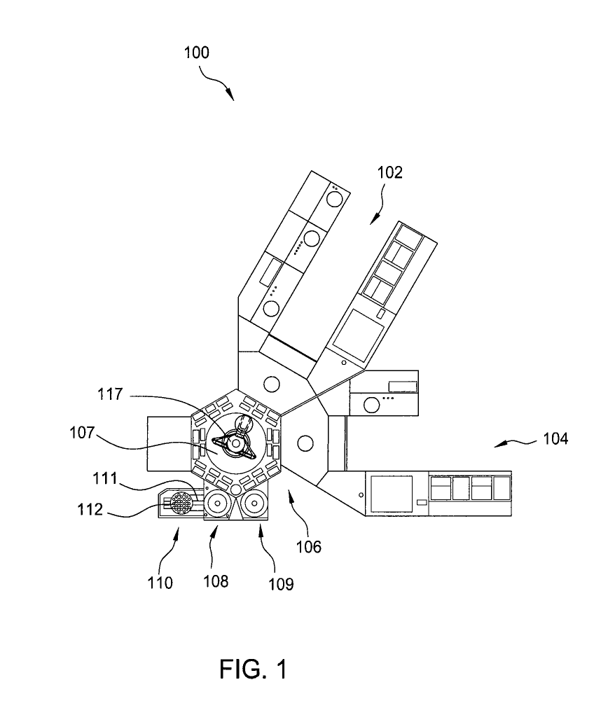

FIG. 1 is a schematic view of a cluster tool 100 in accordance with one embodiment of the present invention. The cluster tool 100 is configured to process substrates using two or more processing chambers. Each processing chamber may be used to perform the same or different processes. In one embodiment, the cluster tool 100 is configured to form nitride compound structures for light emitting diodes (LED).

The cluster tool 100 comprises a transfer chamber 106 having a transfer region 107. The cluster tool 100 comprises a first processing chamber 102 and a second processing chamber 104 coupled to the transfer chamber 106. In one embodiment, the processing chambers 102, 104 may be configured to deposit layers for a LED structure. The processing chambers 102, 104 may be a hydride vapor phase epitaxial (HVPE) chamber or a metal organic chemical vapor deposition (MOCVD) chamber.

A robot assembly 117 is disposed in the transfer region 107 and configured to transfer substrates to and from the first and second processing chambers 102, 104. In one embodiment, the robot assembly 117 comprises a heating element and is configured to transfer substrates while heating the substrates to a high temperature or maintaining the substrate at a high temperature.

The cluster tool 100 further comprises a load lock chamber 108 coupled with the transfer chamber 106 and a load station 110 coupled with the load lock chamber 108. The load lock chamber 108 and the load station 110 are configured to load substrates to the first processing chamber 102 and the second processing chamber 104 through the transfer chamber 106. In one embodiment, the cluster tool 100 further comprises a batch load lock chamber 109, configured for storing a plurality of substrate carriers, coupled with the transfer chamber 106.

The load station 110 is configured as an atmospheric interface to allow an operator to load a plurality of substrates for processing into the confined environment of the load lock chamber 108, and to unload a plurality of processed substrates from the load lock chamber 108. In one embodiment, substrates for processing may be grouped in batches and transported by a conveyor tray 111 on a carrier plate 112. In another embodiment, the load station 110 may be an automatic loading station configured to transfer substrates between carrier plates and transferring cassettes.

The load lock chamber 108 provides an interface between the atmospheric environment of the load station 110 and the controlled environment of the transfer chamber 106. Substrates are transferred between the load lock chamber 108 and the load station 110 via the slit valve and between the load lock chamber 108 and the transfer chamber 106 via another slit valve. In one embodiment, the load lock chamber 108 may comprise multiple carrier supports that are vertically stacked. The carrier supports may be vertically movable to facilitate loading and unloading of a carrier plate 112.

The load lock chamber 108 is coupled to a pressure control system (not shown) which pumps down and vents the load lock chamber 108 to facilitate passing the substrate between the vacuum environment of the transfer chamber 106 and the substantially ambient (e.g., atmospheric) environment of the load station 110. In addition, the load lock chamber 108 may also comprise features for temperature control.

The transfer chamber 106 is generally maintained at a vacuum state or a low pressure state. In one embodiment, the transfer chamber 106 may have a controlled environment maintained by an inert gas, such as helium gas and nitrogen gas, a reducing gas, such as ammonia, or combinations thereof.

The robot assembly 117 is operable to transfer substrates among the load lock chamber 108, the batch load lock chamber 109, the processing chamber 104 and the processing chamber 102. In one embodiment, the robot assembly 117 may comprise heated end effectors configured to keep the substrates at elevated temperature during transfer. In one embodiment, the robot assembly 117 is configured to keep substrates at a temperature higher than about 350° C. during transfer among the processing chambers. In one embodiment, the robot assembly 117 is configured to heat the substrates to higher than about 700° C. In another embodiment, the robot assembly 117 is configured to heat the substrates between about 700° C. and about 1100° C.

The batch load lock chamber 109 having a cavity for storing a plurality of substrates placed on the carrier plates 112 therein. A storage cassette may be moveably disposed within the cavity. The storage cassette may comprise a plurality of storage shelves supported by a frame. In one embodiment, the batch load lock chamber 109 may be configured to clean the substrates prior processing. In one embodiment, the batch load lock chamber 109 may have one or more heaters configured to heat the substrates disposed therein and may be connected to an inert gas source and/or a cleaning gas source to perform a thermal cleaning of the substrates prior to processing.

During an operation, for example manufacturing LED devices, a carrier plate 112 containing a batch of substrates is loaded on the conveyor tray 111 in the load station 110. The conveyor tray 111 is then moved through a slit valve into the load lock chamber 108, placing the carrier plate 112 onto the carrier support inside the load lock chamber 108, and the conveyor tray returns to the load station 110. While the carrier plate 112 is inside the load lock chamber 108, the load lock chamber 108 is pumped and purged with an inert gas, such as nitrogen, in order to remove any remaining oxygen, water vapor, and other types of contaminants.

After the batch of substrates have been conditioned in the batch load lock chamber 109, the robot assembly 117 may pick up the carrier plate 112 and transfer the carrier plate 112 to the processing chamber 102 for a MOCVD or HVPE process. In one embodiment, the robot assembly 117 heats the carrier plate 112 and the substrates thereon to a temperature close to the temperature in the processing chamber 102 during transfer so that the carrier plate 112 can be disposed on the heated processing chamber 102 without thermal shock. Induction heating may be used to achieve rapid heating and without heating up the robot assembly 117 itself. During processing, such as in HVPE processing, the substrates may be heated in the processing chamber 102 to a temperature up to about 1100° C.

After processing in the processing chamber 102, the robot assembly 117 picks up the carrier plate 112 from the processing chamber 102 without waiting for the carrier plate 112 to cool down. To avoid thermal shock to the carrier plate 112 and the substrates, the induction heating element in the robot assembly 117 is activated to maintain the high temperature of the carrier plate 112 and the substrates and to prevent dramatic temperature drop. In one embodiment, an RF power source is applied to the induction heating element in the robot assembly 117 and the current and/or duration of the RF power may be adjusted to maintain the carrier plate 112 at a desired temperature range.

The carrier plate 112 is transferred from the processing chamber 102 to the processing chamber 104 for another process, for example a MOCVD process. In one embodiment, the processing chamber 104 may be heated at a temperature about 800° C., and the carrier plate 112 may be maintained at a temperature between 700° C. to about 800° C. during transferring. Similarly, after processing in the processing chamber 104, the robot assembly 117 picks up the carrier plate 112 from the processing chamber 104 without waiting for the carrier plate 112 to cool down. The induction heating element in the robot assembly 117 is activated to maintain the high temperature of the carrier plate 112 and the substrates and to prevent dramatic temperature drop.

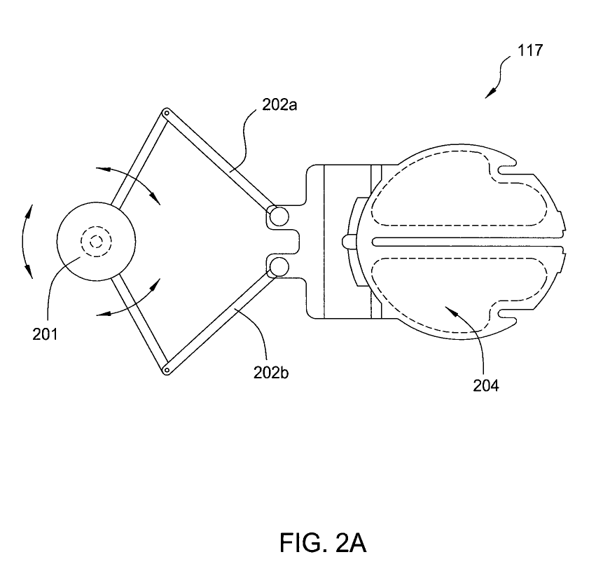

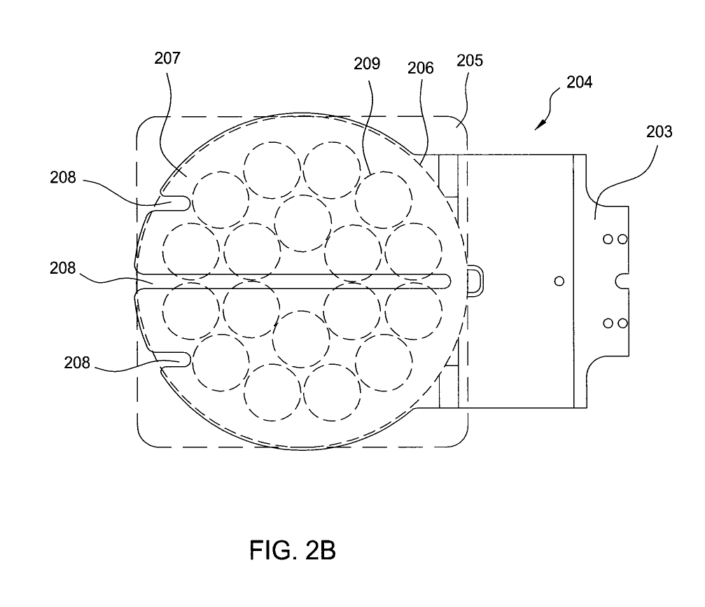

FIG. 2A is a schematic top view of a robot assembly 117 in accordance with one embodiment of the present invention. The robot assembly 117 includes arms 202a, 202b coupled to rotatable two hubs 201. The hubs 201 are connected to an actuator configured to rotate the hubs 201. A transfer blade 204 is mounted on the arms 202a, 202b. The transfer blade 204 is configured to support and secure a substrate or a substrate carrier thereon. The transfer blade 204 comprises an induction heating assembly configured to heat the substrate and/or the substrate carriers disposed thereon. The arms 202a, 202b extend and retract when the hubs 201 rotate relative to one another along opposite direction. The hubs 201 rotate at the same speed along the same direction, the arms 202a, 202b and the transfer blades 204 rotate about the hubs 201.

FIG. 2B is a schematic top view showing the robot blade 204 supporting a substrate carrier. The robot blade 204 has a wrist end 203 configured to mount to an arm assembly, such as the arms 202a, 202b and the hubs 201. The robot blade 204 also has a supporting end 207 configured to support substrates and/or substrate carriers thereon. The supporting end 207 comprises one or more induction heating elements configured to provide induction heating energy towards the substrates and/or substrate carrier during transferring. In one embodiment, the supporting end 207 may have one or more slits 208 formed therethrough to allow lifting pins configured to pick up and drop off the substrates and substrate carriers. The blade 204 has raised areas functioning as stops configured to secure a substrate/carrier thereon. In one embodiment, the blade 204 may have two sets of stops configured to secure a squared carrier 205 and a circular carrier 206 respectively. The carriers 205, 206 are configured to support and secure a plurality of substrates 209.

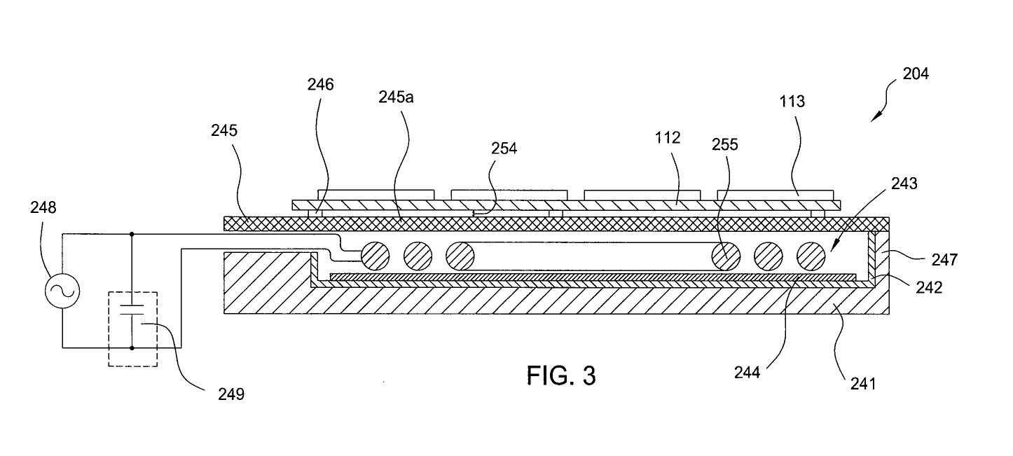

FIG. 3 is a schematic section view of the blade 204 for transferring substrates according to an embodiment of the invention. The blade 204 comprises a base plate 241 configured to provide structural support, an induction heating assembly 243 disposed on the base plate 241, and a top plate 245 disposed over the induction heating assembly 243. The top plate 245 may have a plurality of bumpers 246 formed on a top surface 245a. The bumpers 246 are small raised areas on the top plate 245. The plurality of bumpers 246 are configured to be in contact with a substrate or a carrier plate 112 and to position the carrier plate 112 at a distance 254 away from the top plate 245. Because there is only minimal contact between the top plate 245 and the carrier plate 112 at the bumpers 240, thermal conduction between the blade 204 and the carrier plate 112 can be mostly prevented and the blade 204 can remain cool while the carrier plate 112 and the substrates 113 are heated to a high temperature from induction heating from the induction heating assembly 243.

The base plate 241 may be formed from a dielectric material, or any material that is not responsive to induction heating. In one embodiment, the base plate 241 is formed from quartz material.

In an embodiment, the base plate 241 may comprise an infrared reflective coating 242 on surfaces facing the induction heating assembly 243. The infrared reflective coating 242 is configured to reflect infrared energy from the induction heating assembly 243 and the heated substrate 113/carrier plate 112 to prevent the base plate 241 from heating up by the infrared energy. In an embodiment, the infrared reflective coating 242 comprises a titanium nitride film. The titanium nitride film may be about 0.5 mm in thickness. In another embodiment, the infrared reflective coating 242 may comprise a gold film.

In one embodiment, the blade 204 further comprises a ferrite liner 244 disposed under the induction heating assembly 243. The ferrite liner 244 is configured to shield the inductive field of the induction heating assembly 243 from the base plate 241, therefore, preventing any induction heating of the base plate 241. In one embodiment, the ferrite line 244 is a foil made of ferrite material with a thickness about 2 mm.

The induction heating assembly 243 generally comprises one or more coils 255 disposed over the base plate 241. Each coil 255 is connected to a RF power source 248 which provides high frequency alternating current to the coil 255. The induction heating assembly 243 further comprises a capacitor 249 coupled to the RF power source 248 in a parallel manner. In one embodiment, the capacitor 249 may be cooled by a fluid coolant, such as water. In one embodiment, the capacitor 249 may be used to adjust the phase of the RF power applied to the one or more coils 255.

The induction heating assembly 243 is configured to rapidly heat a substrate or a substrate carrier made of electrically conducting material by applying a RF current to the one or more coils 255. During heating, the high frequency alternating current in the one or more coils 255 causes eddy currents within an electrically conducting object being heated. The resistance to the eddy current in the electrically conducting object leads to Joule heating of the object.

Embodiments of the present invention comprise controlling induction heating by controlling one or more of operating parameters, such as the frequency of the RF power source 248, duration of the RF power applied, power of the RF power source 248, spacing between the one or more coils 255 and the object being heated, such as the carrier plate 112, and spacing between neighboring wires of the coil 255. In one embodiment, the frequency of the RF power source is about 40 kHz to about 100 kHz. In another embodiment, the frequency of the RF power source is about 45 kHz to about 65 kHz. In another embodiment, the frequency of the RF power source is below about 50 kHz. In one embodiment, the power of the RF power source is about 10 kW. In one embodiment, a carrier plate 112 may be heated by the coils 255 to about 1000° C. in about 20 seconds.

The carrier plate 112 may be made from a material subject to induction heating. In one embodiment, the carrier plate 112 is made of graphite. In another embodiment, the carrier plate 112 is made of graphite coated with silicon carbide. In another embodiment, the carrier plate 112 is made of silicon carbide.

Each of the one or more coils 255 is a planar spiral coil wound from a cable having a plurality of wires individually wrapped in an insulator. In one embodiment, each planar spiral coil may have about 10 turns. In another embodiment, neighboring planar spiral coils may be wound along opposite directions so that, when RF power of the same phase is applied to the neighboring coils, the currents within outer portion of the neighboring planar spiral coils are of the same direction, therefore, do not cancel one another. Alternatively, neighboring planar spiral coils may be wound along the same direction, and a phase alternating capacitor may be used within the circuit of one of the coil to make sure that currents within wires of the neighboring coils are not off opposite directions.

The top plate 245 is generally fabricated from a dielectric material which is not subject to induction heating. In one embodiment, the top plate 245 is also made of an infrared transparent material. In one embodiment, the top plate 245 is made of quartz. In one embodiment, the top plate 245 is also coated with an infrared reflective coating, such as a titanium nitride film or a gold film.

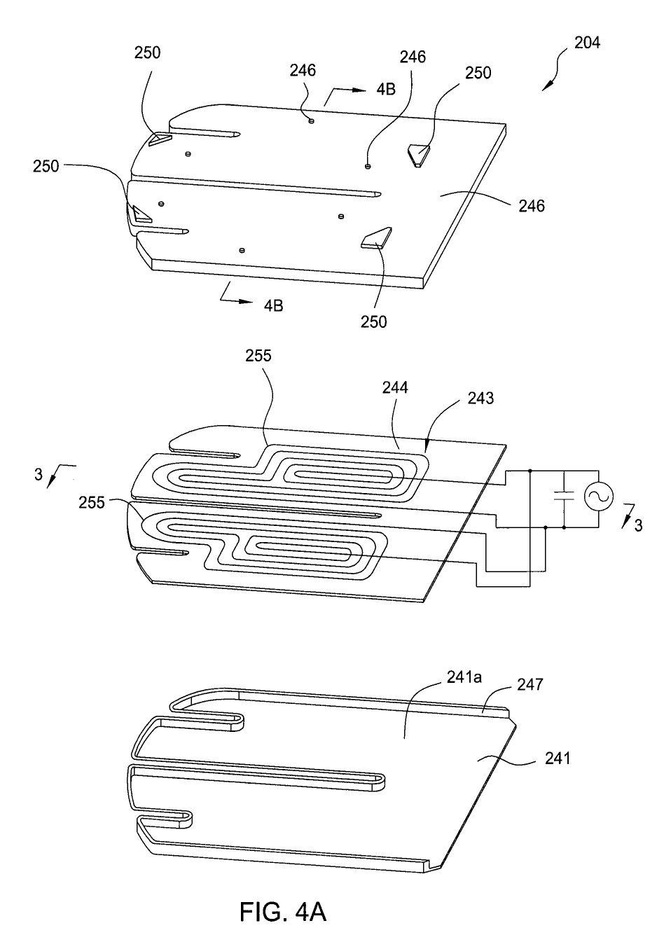

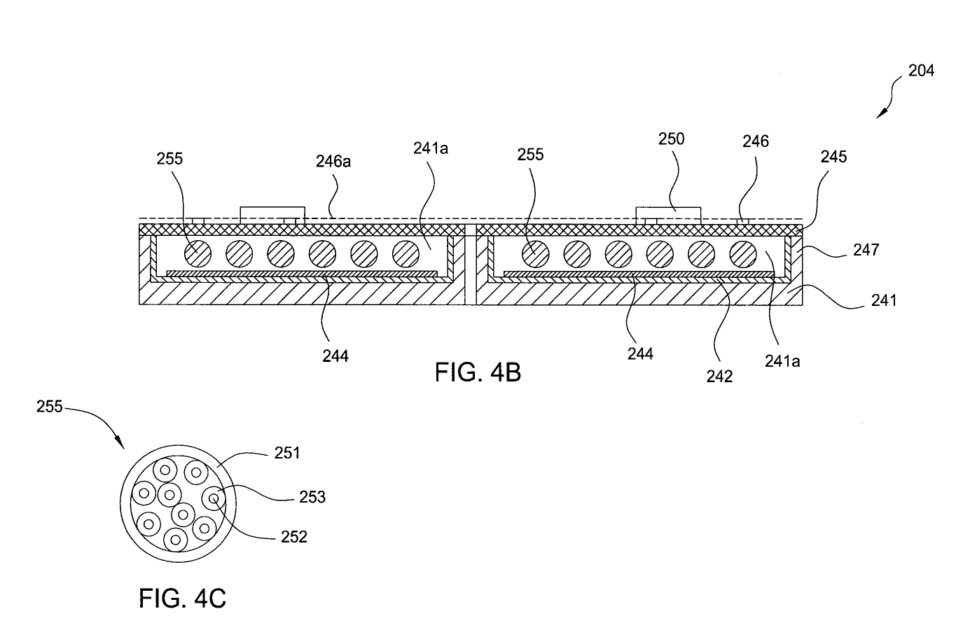

FIG. 4A is an exploded view of the blade 204 according to an embodiment. The base plate 241 includes sidewalls 247 extending upwards along the outer edge. The sidewalls 247 and the bottom of the base plate 241 form a cavity 241a. The base plate 241 may be coated with infrared reflective coating on the inner surfaces thereof. As one example, a ferrite liner 244 may be disposed on the bottom of the base plate 241. Two planar spiral coils 255 are disposed on the ferrite liner 244. The two planar spiral coils 255 may be wound in opposite directions. The top plate 245 rests on the sidewalls 247 of the base plate 241. The top plate 245 has a plurality of bumpers 246 and stops 250 formed thereon. The bumpers 246 are configured to provide support to object being heated with minimal contact. The stops 250 are higher than the bumpers 246 and are configured to secure an object being heated from lateral motions.

FIG. 4B is a sectional side view of the blade 204 of FIG. 4A. The bumpers 246 define a supporting plane 246a. In one embodiment, the bumpers 246 have a height of about 0.5 mm and the stops 250 are about 0.75 mm higher than the supporting plane 246a. In one embodiment, the top plate 245 may have a thickness of about 1 mm. The cavity 241a may have a height of about 10.5 mm.

FIG. 4C is a sectional view of the coil 255 for the induction heating assembly 243 in accordance with one embodiment of the present invention. The coil 255 may be wound by a bundled wire to obtain increased surface area for RF current capacity. In one embodiment, the coil 255 includes a plurality of wires 252 each wrapped in an insulator 253. The plurality of wires 252 are bundled in an insulator 251. In one embodiment, the coils 255 are wound using Litz wires. In one embodiment, the wire of the coils 255 may have a diameter of about 8 mm.

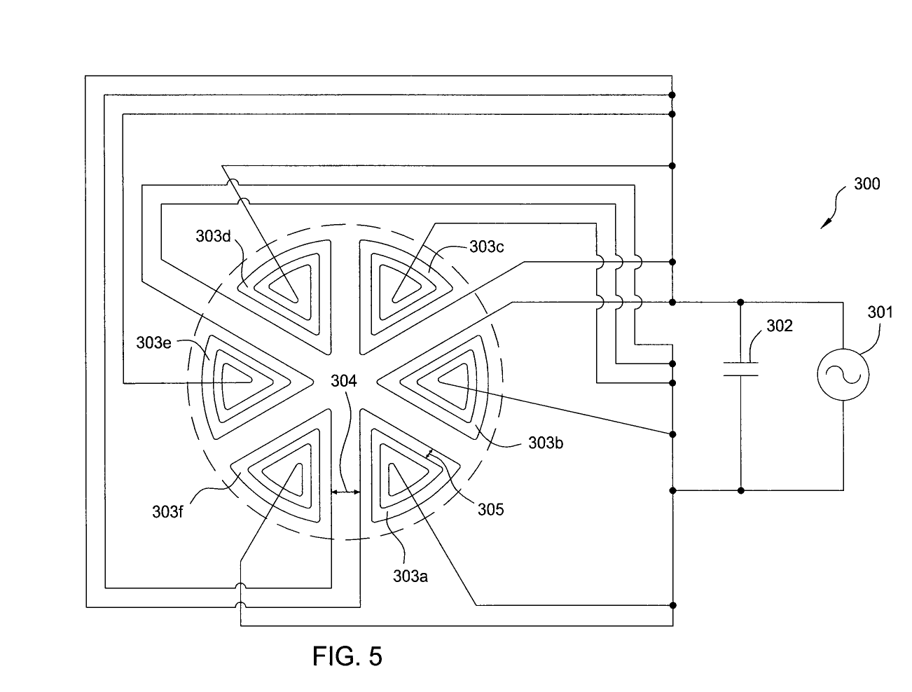

As discussed above, one or more coils may be used in providing induction heating. The one or more coils may be arranged according to the heating needs. In one embodiment, as shown in FIG. 5, a coil assembly 300 comprises six planar spiral coils 303a, 303b, 303c, 303d, 303e, and 303f used to provide induction heating to a substantially circular object, such as substrate carrier configured to carry a plurality of sapphire substrates. Each coil 303a, 303b, 303c, 303d, 303e, and 303f is substantially triangular with neighboring coils wound in opposite directions. Distance 304 indicates the distance between leading wires of neighboring coils. Distance 305 indicates distance between neighboring wires within a coil. In one embodiment, the distance 304 is greater than the distance 305. The planar spiral coils 303a, 303b, 303c, 303d, 303e, and 303f are coupled to an RF power source 301. A capacitor 302 is coupled to the RF power source 301 in a parallel manner.

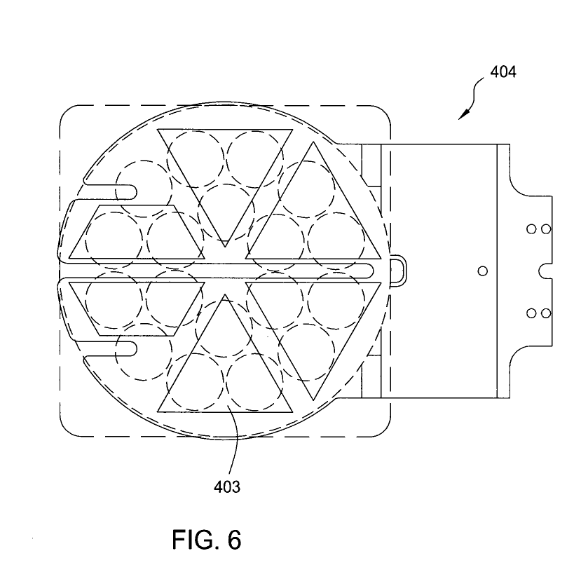

FIG. 6 schematically illustrates a coil arrangement in a robot blade 404 in accordance with one embodiment of the present invention. Six coil assemblies 403 are arranged on the robot blade 404. In one embodiment, each coil assembly 403 may comprise two parallel coils connected to two separate power supplies. In one embodiment, powers with different frequencies are applied to the parallel coils in each coil assembly 403.

Embodiments of the present invention also provide methods and apparatus for inductively heating substrates and/or carriers using induction heating elements positioned along a transfer path, for example in transfer chambers and load locks. In one embodiment, one or more induction heating elements may be disposed outside a transfer chamber and configured to heat substrates or carriers while the substrates and carriers are within the transfer chamber. The one or more induction heating elements may be positioned on a lid of the transfer chamber.

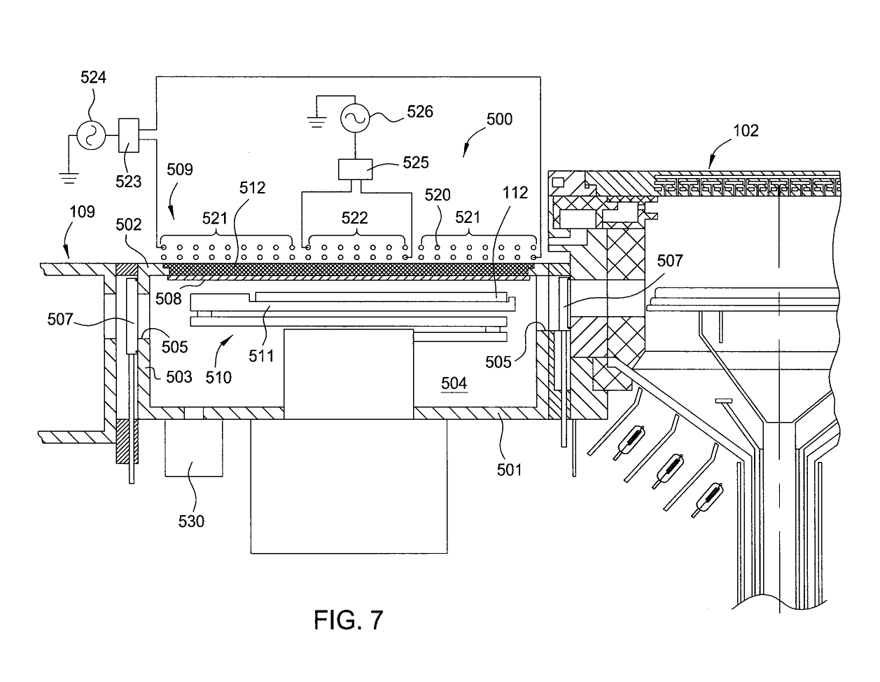

FIG. 7 is a sectional view of a transfer chamber 500 with one or more induction heating elements according to one embodiment of the present invention. The transfer chamber 500 is generally used in a cluster tool, such as the cluster tool 100 of FIG. 1, to facilitate substrate transferring among load locks and processing chamber.

The transfer chamber 500 comprises a chamber bottom 501, sidewalls 503 disposed over the chamber bottom 501, and a chamber lid 502 disposed over the sidewalls 503. The chamber bottom 501, sidewalls 503 and chamber lid 502 define a transfer volume 504. A robot 510 is disposed within the transfer volume 504. The robot 510 has a robot blade 511 configured to support and transfer a carrier plate 112. In one embodiment, the robot blade 511 comprises induction heating elements, similar to robot blades described above. In another embodiment, the robot blade 511 does not include any heaters.

A plurality of slit valve openings 505 are formed through the sidewalls 503. Each slit valve opening 505 provides an interface with other chambers, such as a processing chamber 102, and a load lock chamber 109. Slit valves 507 may be used to selectively open and close the slit valve openings 505 so that the transfer volume 504 can be selectively in fluid communication with the chambers connected to the transfer chamber 500. When the slit valve 507 is open, the robot blade 511 can extend through the slit valve opening 505 to pick up or drop off a carrier plate 112 in the chamber connected thereto.

In one embodiment, a vacuum pump 530 is connected to the transfer volume 504 so that the transfer chamber 500 can be maintained at a vacuum state or a low pressure state. In another embodiment, the transfer volume 504 has a controlled environment maintained by an inert gas, such as helium gas and nitrogen gas, a reducing gas, such as ammonia, or combinations thereof.

The transfer chamber 500 comprises an induction heating assembly 509 disposed outside the transfer chamber. In one embodiment, the induction heating assembly 509 is disposed adjacent the chamber lid 502. The chamber lid 502 has a window 512. The induction heating assembly 509 is configured to heat substrates on the carrier plate 112 in the transfer chamber 500 through the window 512.

The induction heating assembly 509 generally comprises one or more coils 520. The coils 520 may be planar spiral coils. In one embodiment, the coils 520 include two parallel rows as shown in FIG. 7. Alternative, the coils 520 may include a single row. The coils 520 may have a circular shape. In one embodiment, the coils 520 are sized appropriately to match diameter of the carrier plate 112 being heated.

The coils 520 may comprise two or more coils for uniform heating. In one embodiment, the coils 520 comprises an inner heating element 522 and an outer heating element 521. The outer heating element 521 is coupled to a first power source 524 and a first heating station 523. The inner heating element 522 is coupled to a second power source 526 and a second heating station 525. Both the first power source 524 and the first heating station 523 are separate and distinct from the second power source 526 and the second heating station 525. The heating elements 522, 521 operate independently from each other so that collectively, a wide range of precise temperature tuning is possible. The heating elements 521, 522 may be spaced from the top of the substrate or the top of the carrier plate 112 by a distance of between about 0.2 inches and about 0.8 inches.

The outer heating element 521 may comprise an induction coil that has between about 8 turns and about 11 turns. In one embodiment, the outer heating element 521 may be arranged in two substantially parallel rows and have an outer diameter of between about 12 inches and about 15 inches. The inner heating element 522 may comprise an induction coil that has between about 6 turns and about 9 turns. In one embodiment, the inner heating element 522 may be arranged in two substantially parallel rows and have an outer diameter of between about 3 inches and about 6 inches. The number of turns and heating element 521, 522 size is not limited to those shown or described. For example, for heating a bigger carrier plate 112, the size and shape of the heating elements 521, 522 can be adjusted accordingly so the concept is not limited to the particular sizes discussed above.

The first heating station 523 and power source 524 may be arranged to supply between about 30 kW of power and about 45 kW of power while the second heating station 525 and power supply 526 may be configured to supply between about 10 kW and about 17 kW of power. In one embodiment, the frequency of the first power source 524 and second power supply 526 may be different.

The inner heating element 522 and the outer heating element 521 are disposed outside of the chamber lid 502 adjacent the window 512. The window 512 is optically transparent. In one embodiment, the window 512 is made of transparent or opaque quartz. In another embodiment, the window 512 may comprise a dielectric material that is electromagnetically transparent. In another embodiment, the window 512 may be a metallic window with slits to reduce eddy currents.

In one embodiment, a coating 508 may be present on the transparent window 512 to reflect heat back into the transfer chamber 500. In one embodiment, the coating 508 may comprise titanium nitride. In another embodiment, the coating 508 may comprise gold. In another embodiment, the coating 508 may comprise tungsten, or any other reflective material that has high reflectivity in the infrared region. In one embodiment, the coating 508 may be present inside of the transfer chamber 500 as shown in FIG. 7. In another embodiment, the coating 508 may be present on outside the transfer chamber 500 on an outside surface of the window 512. The coating 508 may have a thickness of between about 0.5 micrometers and about 2.0 micrometers. The coating 508 permits the heat to enter the transfer 500 with minimal reflectance back to the induction heating assembly 509. The coating 508 also functions to reflect any heat within the transfer chamber 500 back into the transfer chamber 500 to minimize the amount of heat loss.

In operation, the induction heating assembly 509 may be activated to heat substrates or maintaining hot substrates at high temperature while the substrate are in the transfer chamber 500 in transit. The induction heating assembly 509 may be used independently or in combination with induction heating in the robot blade 511.

The induction heating in the transfer chamber 500 are advantageous because they are induction heating elements rather than resistive heating elements. The induction heating elements are more efficient than resistive heating elements because they utilize less energy and are powered by an RF power source. The induction heating elements do not heat all of the material (such as the entire chamber), but rather, the heat is focused onto the predetermined area (such as the substrates and the carriers).

To facilitate understanding, identical reference numerals have been used, where possible, to designate identical elements that are common to the figures. It is contemplated that elements disclosed in one embodiment may be beneficially utilized on other embodiments without specific recitation.

While the foregoing is directed to embodiments of the present invention, other and further embodiments of the invention may be devised without departing from the basic scope thereof, and the scope thereof is determined by the claims that follow.

What is claimed is:

1. A robot blade assembly for supporting a substrate or a substrate carrier thereon, comprising:
a base plate;
an induction heating assembly disposed on the base plate; and
a top plate disposed above the induction heating assembly;

2. The robot blade assembly of claim 1, wherein the induction heating assembly comprises one or more spiral coils.

3. The robot blade assembly of claim 2, wherein the one or more spiral coils are planar and are not overlapping with one another.

4. The robot blade assembly of claim 3, wherein each of the one or more spiral coils is wound at an opposite direction to a neighboring spiral coil.

5. The robot blade assembly of claim 2, wherein the one or more spiral planar coils are wound from a cable comprising a plurality of individually insulated wires.

6. The robot blade assembly of claim 2, wherein the top plate has a plurality of pumps configured to provide a spacing between the top plate and the substrate or substrate carrier supported thereon.

7. The robot blade assembly of claim 6, wherein the top plate comprises an infrared transparent dielectric material.

8. The robot blade assembly of claim 2, further comprising a ferrite liner disposed between the base plate and the induction heating assembly, wherein the ferrite liner is configured to reflect electromagnetic field.

9. The robot blade assembly of claim 2, wherein the base plate comprises an infrared reflective film disposed on a surface facing the induction heating assembly.

10. A cluster tool, comprising:
a transfer chamber having a transfer volume;
a load lock coupled to transfer chamber;
one or more processing chambers coupled to the transfer chamber, wherein the one or more processing chambers are configured to processing substrates at elevated temperature;
a substrate transfer mechanism disposed in the transfer volume and configured to transfer substrates among the load lock and the one or more processing chambers; and
an induction heating assembly configured to heat substrates being transferred by the substrate transfer mechanism.

11. The cluster tool of claim 10, wherein the induction heating assembly comprises one or more coils disposed over the transfer chamber, and the one or more coils are configured to inductively heat substrates disposed on the substrate transfer mechanism while the substrates are in the transfer volume.

12. The cluster tool of claim 10, wherein the substrate transfer mechanism comprises:
a blade assembly for supporting a substrate or a substrate carrier thereon, wherein the induction heating assembly is disposed in the blade assembly, the blade assembly comprises:
a base plate, wherein the induction heating assembly is disposed on the base plate; and
a top plate disposed above the induction heating assembly; and
an arm assembly, wherein the blade assembly is mounted on the arm assembly.

13. The cluster tool of claim 12, wherein the induction heating assembly comprises one or more spiral coils.

14. The cluster tool of claim 13, wherein the one or more spiral coils are planar and not overlapping with one another.

15. The cluster tool of claim 14, wherein each of the one or more spiral coils is wound at an opposite direction to a neighboring spiral coil.

16. The cluster tool of claim 12, wherein the blade assembly further comprises a ferrite liner disposed between the base plate and the induction heating assembly, wherein the ferrite liner is configured to reflect electromagnetic field.

17. The cluster tool of claim 12, wherein the base plate comprises an infrared reflective film disposed on a surface facing the induction heating assembly.

18. A method for processing one or more substrates, comprising:
transferring the one or more substrates from a first chamber to a second chamber by a transfer mechanism while heating the one or more substrates using an induction heating element to a first temperature; and
processing the one or more substrates in the second chamber at a second temperature, wherein the first temperature is substantially close to and lower than second temperature.

19. The method of claim 18, wherein heating the one or more substrates using an induction heating comprises:
applying RF power source to one or more induction heating element disposed in a blade of the transfer mechanism, wherein the blade supports the one or more substrates during transfer.

20. The method of claim 18, wherein heating the one or more substrates using an induction heating comprises applying RF power source to one or more induction heating element disposed over the first chamber.
